(19) United States
(12) Patent Application Publication
(10) Pub. No.: US 2021/0082533 A1
(43) Pub. Date: Mar. 18, 2021

(54) SEMICONDUCTOR MEMORY DEVICE AND METHOD OF MANUFACTURING SEMICONDUCTOR MEMORY DEVICE

(71) Applicants: Kabushiki Kaisha Toshiba, Tokyo (JP); Toshiba Electronic Devices & Storage Corporation, Tokyo (JP)

(72) Inventors: Kaoru Hama, Yokohama Kanagawa (JP); Junji Takahashi, Yokohama Kanagawa (JP)

(21) Appl. No.: 16/804,330

(22) Filed: Feb. 28, 2020

(30) Foreign Application Priority Data
Sep. 12, 2019 (JP) 2019-166201

(51) Int. Cl. G11C 17/18; H01L 27/112; G11C 17/16

(52) U.S. Cl. CPC G11C 17/18; G11C 17/16; H01L 27/11206

(57) ABSTRACT

According to one embodiment, a semiconductor memory device includes a MOS transistor and a drive circuit. The MOS transistor has a gate and a gate insulating film. The drive circuit is coupled to the gate and supplies a first voltage that destroys the gate insulating film or a second voltage lower than the first voltage. The drive circuit applies the first voltage to the gate in a first write to the MOS transistor, and applies the second voltage to the gate in a second write to the MOS transistor.

### CROSS-REFERENCE TO RELATED APPLICATIONS

This application is based upon and claims the benefit of priority from Japanese Patent Application No. 2019-166201, filed on Sep. 12, 2019; the entire contents of which are incorporated herein by reference.

### FIELD

Embodiments described herein relate generally to a semiconductor memory device and a method of manufacturing the semiconductor memory device.

### BACKGROUND

Conventionally, a technique for rewriting information twice by coupling an additional device in series to a fuse element representing one-bit information has been disclosed.

However, two elements having different breakdown characteristics are required to form one bit in the prior art. For this reason, in the prior art, device development costs and process manufacturing costs increase. Furthermore, the silicon area increases in the prior art.

### BRIEF DESCRIPTION OF THE DRAWINGS

FIG. 1 is a schematic diagram illustrating an outline of a configuration of a semiconductor memory device according to an embodiment;

FIG. 2 is a cross-sectional view illustrating an N-channel MOS transistor as an example of a memory cell according to the embodiment;

FIG. 3 is a circuit diagram illustrating an example of a first voltage generation circuit, a second voltage generation circuit, and a switch circuit in a drive circuit according to the embodiment;

FIG. 4 is a view illustrating an example of a cross section of a MOS transistor related to a first write according to the embodiment;

FIG. 5 is a view illustrating an example of a cross section of a MOS transistor related to a second write according to the embodiment;

FIG. 6 is a schematic top view illustrating an example of an unwritten MOS transistor, a first-written MOS transistor, and a second-written MOS transistor according to a modification of the embodiment;

FIG. 7 is a graph indicating an example of the relationship between a breakdown voltage and a temperature according to an application example of the embodiment;

FIG. 8 is a view illustrating an example of the positional relationship between a MOS transistor and a light irradiation device according to the application example of the embodiment;

FIG. 9 is a flowchart illustrating an example of a procedure of assist erase processing according to the application example of the embodiment; and

FIG. 10 is a flowchart illustrating an example of a procedure of optical assist writing processing according to the application example of the embodiment.

### DETAILED DESCRIPTION

In general, according to one embodiment, a semiconductor memory device includes a MOS transistor and a drive circuit. The MOS transistor has a gate and a gate insulating film. The drive circuit is coupled to the gate. The drive circuit supplies a first voltage that destroys the gate insulating film or a second voltage lower than the first voltage. The drive circuit applies the first voltage to the gate in the first write to the MOS transistor. The drive circuit applies the second voltage to the gate in the second write to the MOS transistor.

The semiconductor memory device and the method of manufacturing the semiconductor memory device according to the embodiment will be explained below in detail with reference to the accompanying drawings. Note that the present invention is not limited to the following embodiment.

### Embodiment

The semiconductor memory device according to the embodiment is, for example, a memory that can be rewritten to a dielectric breakdown-type one-time programmable (OTP) memory cell.

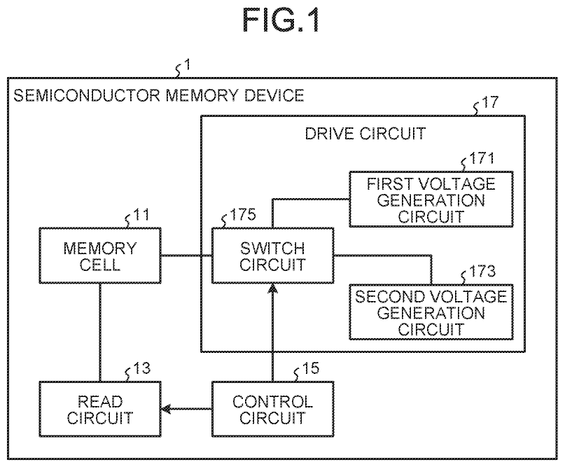

FIG. 1 is a schematic diagram illustrating an outline of a configuration of the semiconductor memory device 1 according to the embodiment. The semiconductor memory device 1 includes a memory cell 11, a read circuit 13, a control circuit 15, and a drive circuit 17. As illustrated in FIG. 1, the memory cell 11 is electrically coupled to the read circuit 13 and the drive circuit 17. The control circuit 15 is electrically coupled to the read circuit 13 and the drive circuit 17. The drive circuit 17 includes a first voltage generation circuit 171, a second voltage generation circuit 173, and a switch circuit 175. As illustrated in FIG. 1, the first voltage generation circuit 171 and the second voltage generation circuit 173 are each electrically coupled to the switch circuit 175. The switch circuit 175 is electrically coupled to the memory cell 11 and the control circuit 15.

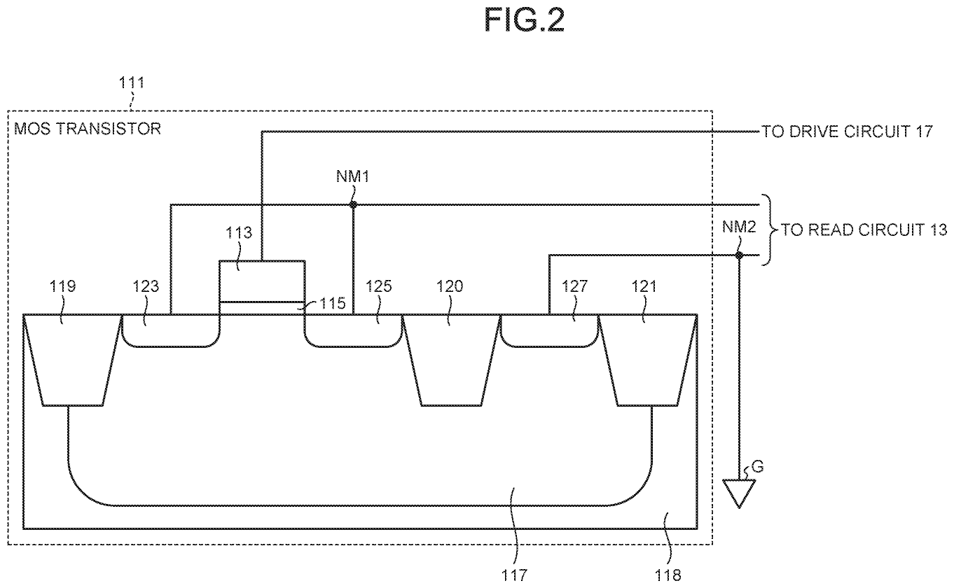

FIG. 2 is a cross-sectional view illustrating an example of an N-channel metal oxide semiconductor (MOS) transistor 111 as an example of the memory cell 11. As illustrated in FIG. 2, the MOS transistor 111 includes a gate 113, a gate insulating film 115, a first AA (Active Area: diffusion layer) 123, a second AA 125, and a P+ type diffusion layer 127. The first AA 123 and the second AA 125 function as electrodes of the MOS transistor 111. The first AA 123 and the second AA 125 are N-type diffusion layers. In the first AA 123 and the second AA 125, when one is a source, the other is a drain. The gate 113 illustrated in FIG. 2 is electrically coupled to the drive circuit 17. Further, the first AA 123 and the second AA 125 are electrically coupled to the read circuit 13. The P+ type diffusion layer 127 is electrically coupled to the read circuit 13.

The gate 113 is formed of polysilicon, for example. Note that metal may be used as a material of the gate 113. At this time, the gate 113 is referred to as “metal gate”. Specifically, the gate insulating film 115 is realized by a gate oxide film such as silicon dioxide. The MOS transistor 111 includes, for example, N+ type polysilicon (hereinafter referred to as “polysilicon”) corresponding to the gate 113, the gate insulating film 115, the P type well 117, and a plurality of shallow trench isolations (STIs) 119, 120, and 121, the first AA 123, the second AA 125, and the P+ type diffusion layer 127.

The P type well 117 is a part of the MOS transistor 111. The P type well 117 is formed in a silicon substrate 118. The gate insulating film 115 is formed on the P type well 117. The gate insulating film 115 is an insulating film having a characteristic of being destroyed by a voltage applied by the drive circuit 17. The gate 113 is formed on the gate insulating film 115. The gate 113 is electrically coupled to the drive circuit 17. The first AA 123 is formed on the surface of the P type well 117 at one end of the gate insulating film 115. An STI 119 is formed on the opposite side of the gate insulating film 115 with respect to the first AA 123. The second AA 125 is formed on a surface of the P type well 117 at the other end of the gate insulating film 115. An STI 120 is formed on the opposite side of the gate insulating film 115 with respect to the second AA 125. On the surface of one end of the P type well 117, the P+ type diffusion layer 127 surrounded by the STIs 120 and 121 is formed.

Output lines from the first AA 123 and the second AA 125 are coupled at a node NM1 and are coupled to the read circuit 13. An output line from the P+ type diffusion layer 127 is electrically coupled to an output line from a ground potential G at a node NM2 and is coupled to the read circuit 13.

The read circuit 13 is electrically coupled to the first AA 123 and the second AA 125 in the MOS transistor 111 via the node NM1. Further, the read circuit 13 is electrically coupled to the P+ type diffusion layer 127 and the ground potential G through the node NM2. The read circuit 13 includes, for example, a sense amplifier. The read circuit 13 reads a bit signal from the memory cell 11. The read circuit 13 amplifies the read bit signal in the sense amplifier and outputs it to the outside of the semiconductor memory device 1. A reading method by the read circuit 13 is not limited to the sense method, and any method can be applied.

The control circuit 15 controls the drive circuit 17 in order to execute the writing at the time of writing bit information to the memory cell 11. By this writing (hereinafter referred to as “first write”), a data state of the MOS transistor 111 comes to a programmed state. The control circuit 15 controls the drive circuit 17 in order to execute the erasure at the time of erasing the bit information written in the memory cell 11. By this erasing (hereinafter referred to as “second write”), the data state of the MOS transistor 111 is rewritten from the programmed state to the erased state. The processing procedure of the operation in the first write and the second write will be described later.

The drive circuit 17 is electrically coupled to the gate 113 and supplies a first voltage that destroys the gate insulating film 115 or a second voltage lower than the first voltage. The drive circuit 17 applies the first voltage to the gate 113 in the first write to the MOS transistor 111 and applies the second voltage to the gate 113 in the second write to the MOS transistor 111. That is, the drive circuit 17 selectively applies the first voltage and the second voltage to the gate 113. FIG. 2 is an example of controlling the voltage on the gate 113 side.

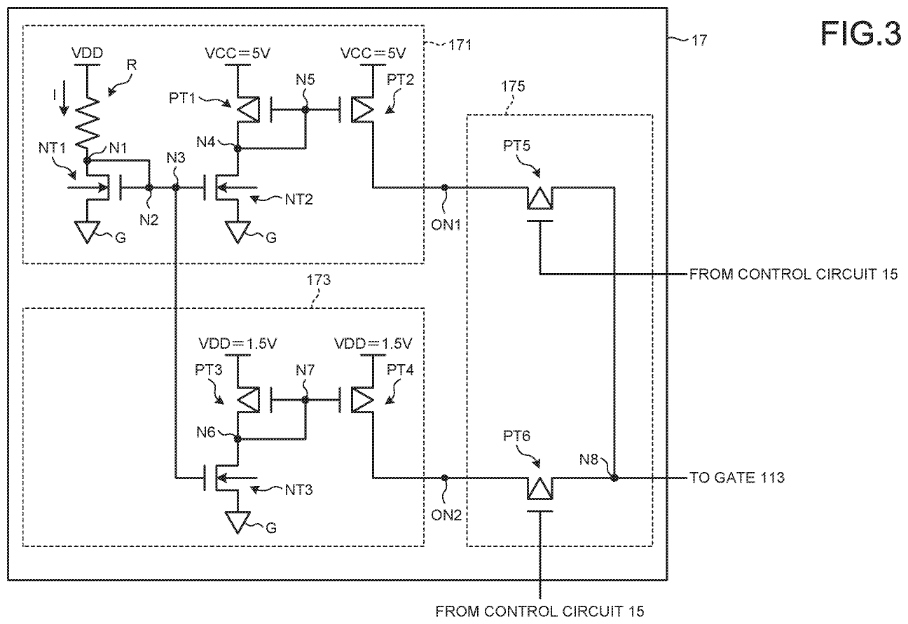

FIG. 3 is a circuit diagram illustrating an example of the first voltage generation circuit 171, the second voltage generation circuit 173, and the switch circuit 175 in the drive circuit 17. The first voltage generation circuit 171 generates a first voltage (hereinafter referred to as “high voltage” (for example, 5 V)) and a first current. The second voltage generation circuit 173 generates a second voltage lower than the first voltage (hereinafter referred to as “low voltage” (for example, 1.5 V)) and a second current. The first voltage generation circuit 171 and the second voltage generation circuit 173 correspond to a power supply circuit. The circuit diagram relating to the first voltage generation circuit 171 and the second voltage generation circuit 173 illustrated in FIG. 3 is an example, and any circuit can be used as long as it can generate a high voltage and a low voltage. For example, the first voltage generation circuit 171 and the second voltage generation circuit 173 may be independent power supply circuits.

The switch circuit 175 switches between a first coupling state in which the first voltage generation circuit 171 and the gate 113 are coupled, and a second coupling state in which the second voltage generation circuit 173 and the gate 113 are coupled. The switch circuit 175 electrically couples the first voltage generation circuit 171 and the gate 113 in the first write to the MOS transistor 111. The switch circuit 175 switches to the first coupling state in the first write and switches to the second coupling state in the second write. In the first write, the gate insulating film 115 is destroyed, and the melted material of the gate 113 enters between the destroyed gate insulating films. Thus, the first write corresponds to forming a conductive path that brings the gate insulating film 115 and the first AA 123 into a conductive state. The conductive path corresponds to a micropath having a narrow path width. The switch circuit 175 electrically couples the second voltage generation circuit 173 and the gate 113 in the second write to the MOS transistor 111. The second write corresponds to fusing the conductive path formed in the first write, that is, electrical decoupling.

The first voltage generation circuit 171 includes a resistor R, a first NMOS transistor NT1, a ground potential G, a second NMOS transistor NT2, a first PMOS transistor PT1, and a second PMOS transistor PT2.

The resistor R is coupled in series between a reference voltage VDD and a node N1. In the first NMOS transistor NT1, a source is electrically coupled to the node N1, a gate is electrically coupled to a node N2, and a drain is electrically coupled to the ground potential G. The node N1 and the node N2 are electrically coupled. In the second NMOS transistor NT2, a source is electrically coupled to the ground potential G, a gate is electrically coupled to a node N3, and a drain is electrically coupled to a node N4. The node N2 and the node N3 are electrically coupled.

In the first PMOS transistor PT1, a source is electrically coupled to a reference voltage VCC (for example, 5 V), a gate is electrically coupled to a node N5, and a drain is electrically coupled to the node N4. The node N4 and the node N5 are electrically coupled. In the second PMOS transistor PT2, a source is electrically coupled to a first output node ON1, a gate is electrically coupled to the node N5, and a drain is electrically coupled to a power supply voltage VCC.

As illustrated in FIG. 3, the first NMOS transistor NT1 and the second NMOS transistor NT2 constitute a first current mirror circuit. Further, the first PMOS transistor PT1 and the second PMOS transistor PT2 form a second current mirror circuit as illustrated in FIG. 3. In the first current mirror circuit, if a mirror ratio of the first NMOS transistor NT1 is 1, and a mirror ratio of the second NMOS transistor NT2 is m, a reference current I is multiplied by m. The reference current I is approximately equal to a value obtained by dividing the difference between the reference voltage VDD and the threshold voltage VthN of the first NMOS transistor NT1 by the resistor R (I=(VDD−VthN)/R).

Further, in the second current mirror circuit, if the mirror ratio of the first PMOS transistor PT1 is np and the mirror ratio of the second PMOS transistor PT2 is mp, the first current output from the first voltage generation circuit 171 corresponds to I×m×(mp/np). In the first voltage generation circuit 171, a plurality of mirror ratios (m, np, mp) are set in advance such that the first current becomes a small current. These mirror ratios are set in advance according to the first write described later. As a result, the first voltage generation circuit 171 generates a small current as the first current. If a fifth PMOS transistor PT5 is turned off, in relation to grounding, the potential at the first output node ON1 rises, and the voltage at the first output node ON1 is the first voltage corresponding to the reference voltage VCC of 5 V, that is, a high voltage.

The second voltage generation circuit 173 includes a third NMOS transistor NT3, a ground potential G, a third PMOS transistor PT3, and a fourth PMOS transistor PT4. In the third NMOS transistor NT3, a source is electrically coupled to the ground potential G, a gate is electrically coupled to the node N3, and a drain is electrically coupled to a node N6. In the third PMOS transistor PT3, a source is electrically coupled to a reference voltage VDD (for example, 1.5 V), a gate is electrically coupled to a node N7, and a drain is electrically coupled to the node N6. In the fourth PMOS transistor PT4, the source is electrically coupled to the second output node ON2, the gate is electrically coupled to the node N7, and the drain is electrically coupled to the reference voltage VDD.

As illustrated in FIG. 3, the third PMOS transistor PT3 and the fourth PMOS transistor PT4 form a third current mirror circuit. In the third current mirror circuit, when a mirror ratio in the third PMOS transistor PT3 is n′p, and a mirror ratio of the fourth PMOS transistor PT4 is m′p, the second current output from the second voltage generation circuit 173 corresponds to I×m×(m′p/n′p). In the second voltage generation circuit 173, a plurality of mirror ratios (m, np, and mp) are set in advance such that the second current becomes a large current, specifically, the second current is larger than the first current. These mirror ratios are set in advance according to the second write described later. Thereby, the second voltage generation circuit 173 generates a large current as the second current. Further, when the sixth PMOS transistor PT6 is turned off, in relation to grounding, the potential at the second output node ON2 rises, and the voltage at the second output node ON2 is a second voltage corresponding to the reference voltage VDD of 1.5 V, that is, a low voltage.

The switch circuit 175 includes a high breakdown voltage fifth PMOS transistor PT5 and a high breakdown voltage sixth PMOS transistor PT6. Note that the sixth PMOS transistor PT6 can also be a low breakdown voltage transistor. At this time, the area of the switch circuit 175 can be reduced compared to the case where the fifth PMOS transistor PT5 and the sixth PMOS transistor PT6 are both configured to have a high breakdown voltage.

In the fifth PMOS transistor PT5, a source is electrically coupled to a node N8, a gate is electrically coupled to the control circuit 15, and a drain is electrically coupled to a source of the second PMOS transistor PT2. In the sixth PMOS transistor PT6, a source is electrically coupled to the node N8, a gate is electrically coupled to the control circuit 15, and a drain is electrically coupled to a source of the fourth PMOS transistor PT4.

For example, the fifth PMOS transistor PT5 and the sixth PMOS transistor PT6 are each turned on when the output pulse from the control circuit 15 is low. Further, at the time of reading, the fifth PMOS transistor PT5 and the sixth PMOS transistor PT6 are each turned off when the output pulse from the control circuit 15 is high. Further, the fifth PMOS transistor PT5 and the sixth PMOS transistor PT6 are controlled by the control circuit 15 so as not to be turned on simultaneously.

Hereinafter, the first write will be described, and then the second write will be described.

(First Write)

The control circuit 15 controls the switch circuit 175 to execute the first write. Specifically, the control circuit 15 outputs a control signal (High) for turning off the sixth PMOS transistor PT6 illustrated in FIG. 3 to the sixth PMOS transistor PT6. The sixth PMOS transistor PT6 is turned off by the control signal, and the electrical coupling between the second voltage generation circuit 173 and the node N8 is cut off. The control circuit 15 outputs a control signal (Low) that turns on the fifth PMOS transistor PT5 illustrated in FIG. 3 to the fifth PMOS transistor PT5. The fifth PMOS transistor PT5 is turned on by the control signal, and the first voltage generation circuit 171 and the gate 113 are electrically coupled. At this time, the first coupling state is realized, a high voltage (first voltage) is applied to the gate 113 of the MOS transistor 111, and a small current is supplied to the gate 113. That is, during the first write, the first voltage generation circuit 171 functions as a high voltage small current generation circuit.

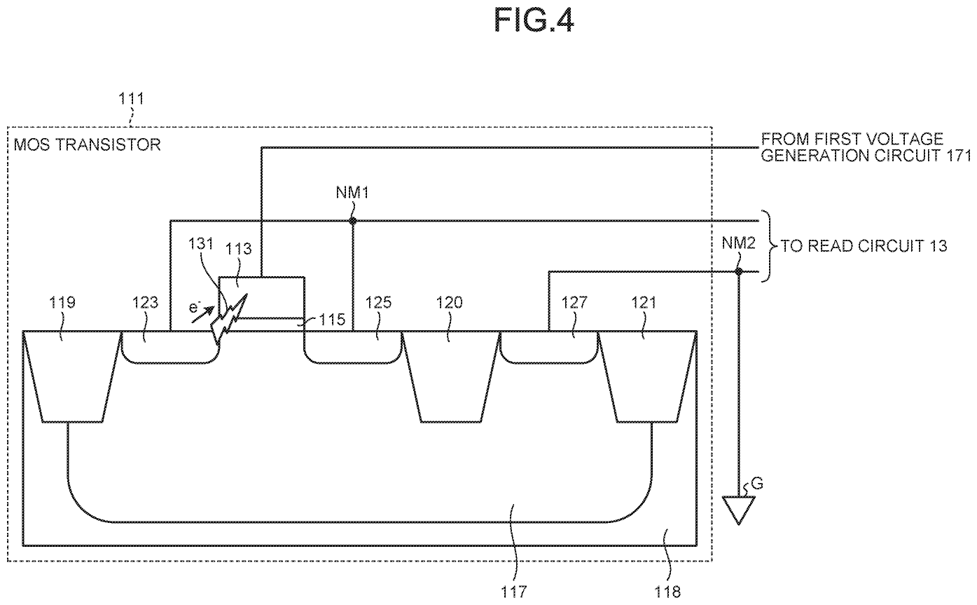

FIG. 4 is a diagram illustrating an example of a cross section of the MOS transistor 111 related to the first write. As illustrated in FIG. 4, a positive high voltage is applied to the gate 113. At this time, for example, electrons are injected from the first AA 123 into the gate 113 through the gate insulating film 115. That is, a small current flows from the first AA 123 to the gate insulating film 115 with a mirror ratio set in advance in the first voltage generation circuit 171. In this process, the electrons injected into the gate insulating film 115 generate Joule heat by losing kinetic energy. Due to the generation of Joule heat, the gate insulating film 115 generates heat. When the temperature of the gate insulating film 115 exceeds a melting point due to heat generation of the gate insulating film 115, the gate insulating film 115 is destroyed. Further, when the electrons reach the gate 113, heat generation corresponding to a difference in energy between a valence band and a conduction band occurs, and the gate 113, that is, polysilicon is melted. The broken portion of the gate insulating film 115 is filled with the melted polysilicon.

Through these processes, the gate insulating film 115 is destroyed in the first write, and a conductive path 131 that makes the gate insulating film 115 conductive is formed. The conductive path 131 is formed between the first AA 123 and the gate 113, whereby the programming for the MOS transistor 111 is completed. Note that, at the time of the first write, a first voltage corresponding to a current that does not fuse the generated conductive path 131 is set. In addition, the application time for applying the first voltage to the gate 113 (hereinafter referred to as “first application time”) is set in advance such that the conductive path 131 is formed.

(Second Write)

The control circuit 15 controls the switch circuit 175 to execute a second write. Specifically, the control circuit 15 outputs a control signal (High) for turning off the fifth PMOS transistor PT5 illustrated in FIG. 3 to the fifth PMOS transistor PT5. By this control signal, the fifth PMOS transistor PT5 is turned off, and the electrical coupling between the first voltage generation circuit 171 and the node N8 is cut off. The control circuit 15 outputs a control signal (Low) for turning on the sixth PMOS transistor PT6 illustrated in FIG. 3 to the sixth PMOS transistor PT6. The sixth PMOS transistor PT6 is turned on by the control signal, and the second voltage generation circuit 173 and the gate 113 are electrically coupled. At this time, the second coupling state is realized, and a low voltage (second voltage) is applied to the gate 113 of the MOS transistor 111. At this time, a second current (large current) larger than the first current (small current) is supplied to the gate 113. That is, during the second write, the second voltage generation circuit 173 functions as a low voltage large current generation circuit.

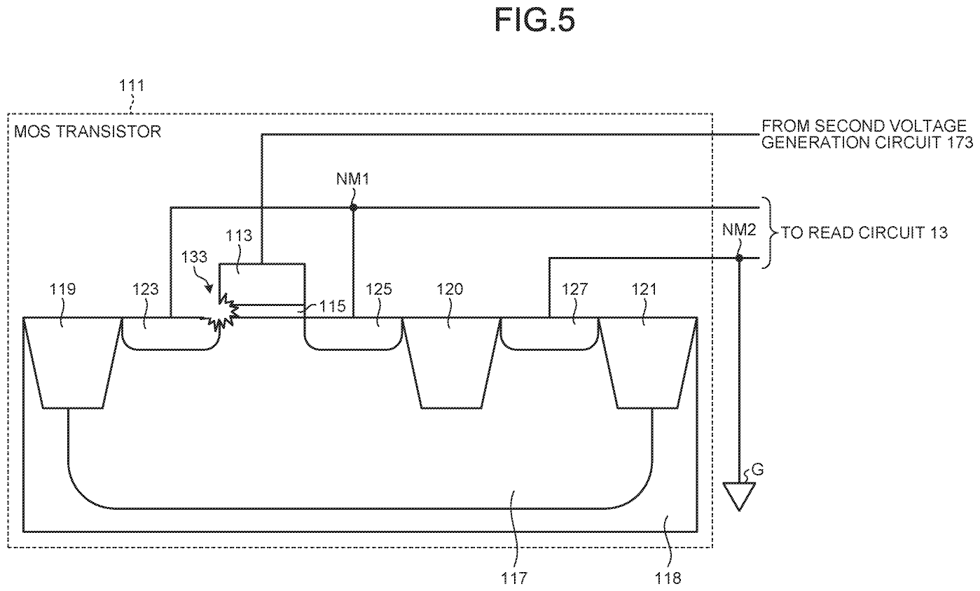

FIG. 5 is a view illustrating an example of a cross section of the MOS transistor 111 related to the second write. As illustrated in FIG. 5, a positive low voltage is applied to the gate 113. A conductive path 131 is formed between the first AA 123 and the gate 113 by the first write. Due to the mirror ratio preset in the second voltage generation circuit 173, a large current flows through the conductive path 131 during the second write. When a large current flows through the conductive path 131, Joule heat is generated in the conductive path 131. Due to the generation of Joule heat, the conductive path 131 generates heat and is fused.

That is, in the second write, the conductive path 131 is fused. The conductive path 131 formed in the first write is fused in the second write, whereby the data state of the MOS transistor 111 is rewritten from a program state to an erase state. As a result, program erasure (Erace) for the MOS transistor 111 is realized. As illustrated in FIG. 5, a region 133 (hereinafter referred to as “fused region”) in which the conductive path 131 is fused is formed at the position of the conductive path 131 by fusing the conductive path 131. An application time during which the second voltage is applied to the gate 113 (hereinafter referred to as “second application time”) is set in advance such that the conductive path 131 is fused.

The first write and the second write for one MOS transistor 111 in the semiconductor memory device 1 have been described above. Note that if the first voltage generation circuit 171 and the second voltage generation circuit 173 respectively function as a high voltage small current generation circuit that generates a high voltage small current and a low voltage large current circuit that generates a low voltage large current, any circuit is applicable without being limited to the circuit configuration illustrated in FIG. 3.

According to the embodiment, the drive circuit 17 is coupled to the gate 113 of the MOS transistor 111 and supplies a high voltage (first voltage) that destroys the gate insulating film 115 of the MOS transistor 111 or low voltage (second voltage), and the drive circuit 17 applies a high voltage to the gate 113 and applies a low voltage to the gate 113. As a result, it is possible to obtain an effect that a state of the memory cell 11 can be changed twice without using two elements having different breakdown characteristics. That is, according to the embodiment, it is possible to provide the semiconductor memory device 1 that can be written twice without using two elements having different breakdown characteristics.

Specifically, in the semiconductor memory device 1 according to the embodiment, the first coupling state and the second coupling are switched by the switch circuit 175 according to the first write and the second write. In the first coupling state, the first voltage generation circuit 171 that generates a high voltage and the gate 113 are electrically coupled, and in the second coupling state, the second voltage generation circuit 173 that generates a low voltage and the gate 113 are electrically coupled. By electrically coupling the first voltage generation circuit 171 and the gate 113 in the first write to the MOS transistor 111, the gate insulating film 115 is destroyed in the first write, and a conductive path 131 that makes the gate insulating film 115 conductive is formed. Further, by electrically coupling the second voltage generation circuit 173 and the gate 113 in the second write to the MOS transistor 111, the conductive path 131 generated in the first write is fused.

From these, according to the semiconductor memory device 1 according to the embodiment, the element area can be made smaller than the element area in the semiconductor memory device using two elements having different breakdown characteristics, and one memory cell 11 can be written twice. Furthermore, since the memory cell 11 in the semiconductor memory device 1 according to the embodiment is an insulating film breakdown type, it is not necessary to develop a new element. Therefore, according to the semiconductor memory device 1 according to the embodiment, the device development cost and the process manufacturing cost are reduced, a voltage breakdown type program (first write and second write) is realized, and multi-bit simultaneous write can be realized.

(Modification)

A modification is that the semiconductor memory device 1 includes a plurality of MOS transistors each including the gate 113, the gate insulating film 115, the first AA 123, the second AA 125, and the P+ type diffusion layer 127. A plurality of the MOS transistors are arranged in one row or array. At this time, the control circuit 15 controls the switch circuit 175 as described above so as to execute the first write and the second write for at least one of the MOS transistors. For example, the output from the switch circuit 175 in FIG. 3 is used as a power supply voltage of a word line between the word line and a bit line. At this time, in the first write and the second write, the word line driver of the address to be programmed is turned on.

The semiconductor memory device 1 according to the modification includes, for example, an initial state MOS transistor in which the first write is not executed (hereinafter referred to as “unwritten Tr”), a program state MOS transistor in which the first write is executed (hereinafter referred to as “first written Tr”), and an erase state MOS transistor in which the second write is executed after the first write (hereinafter referred to as “second written Tr”).

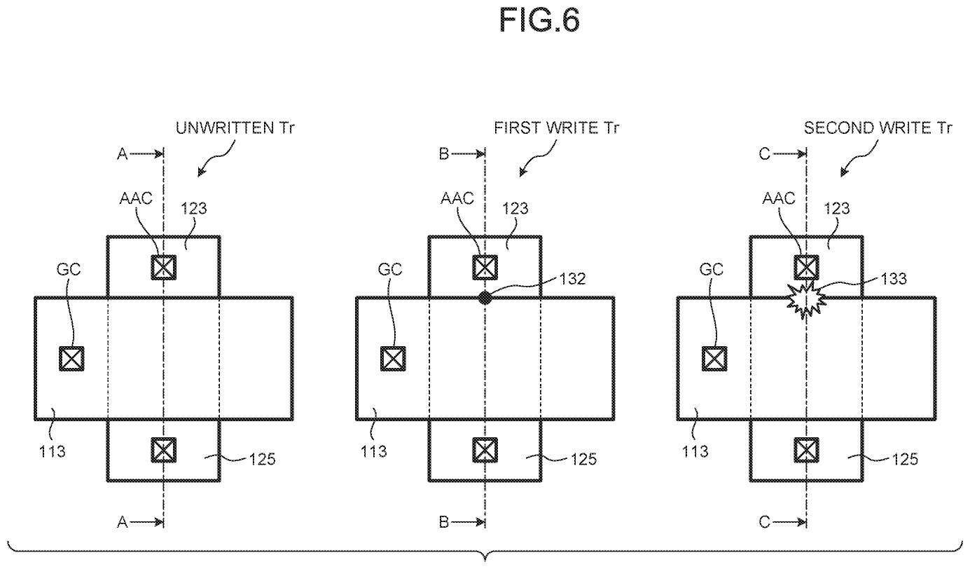

FIG. 6 is a schematic top view illustrating an example of the unwritten Tr, the first written Tr, and the second written Tr according to the modification of the embodiment. FIG. 2 corresponds to the cross section taken along the cutting line AA of FIG. 6. FIG. 4 corresponds to the cross section taken along the cutting line BB of FIG. 6. FIG. 5 corresponds to the cross section taken along the cutting line CC of FIG. 6. As illustrated in FIG. 6, when the first write to apply a high voltage between a gate contact GC and a first AA 123 contact AAC is performed for the unwritten Tr, a region 132 related to the conductive path 131 is formed between the gate 113 and the first AA 123.

In addition, as illustrated in FIG. 6, when the second write to apply a low voltage between the gate contact GC and the first AA 123 contact AAC is performed for the first written Tr, the conductive path 131 is fused to form a fused region 133 at the position of the region 132 related to the conductive path 131. For example, the fused region 133 is generated by missing a part of the gate 113 as illustrate in FIGS. 5 and 6. In the semiconductor memory device 1 according to the modification, as illustrated in FIG. 6, three MOS transistors (unwritten Tr, first written Tr, and second written Tr) corresponding to three types of data states are mixed. That is, in the semiconductor memory device 1 according to the modification, the MOS transistor which has been applied with the first voltage among a plurality of the MOS transistors has a region relating to the conductive path 131 formed by destruction of the gate insulating film 115, and the MOS transistor which has been applied with the second voltage after the application of the first voltage among a plurality of the MOS transistors has a fused region 133 formed by fusing the conductive path 131 formed by destruction the gate insulating film 115.

### Application Example

An application example relates to a method of manufacturing the semiconductor memory device 1 and locally irradiates the gate 113 with light having a wavelength corresponding to the material of the gate 113 in at least one of the first write and the second write. The wavelength corresponding to the material of the gate 113 corresponds to, for example, a wavelength at which light absorption at the gate 113 is maximized. When the material of the gate 113 is polysilicon, the band gap of the polysilicon is, for example, 1.1 eV and absorbs infrared rays. Hereinafter, for the sake of specific explanation, it is assumed that light with which the gate 113 having polysilicon is irradiated is an infrared (hereinafter referred to as “IR”) laser. When the gate 113 is irradiated with the IR laser, the gate 113 absorbs the IR laser. The temperature of the gate 113 rises due to absorption of the IR laser. For this reason, Joule heat required for destroying the gate insulating film 115 and fusing the conductive path 131 is reduced.

In the first write, which is a program process, in the insulating film breakdown-type memory cell 11, the gate insulating film 115 is melted, and as polysilicon moves to the melted gate insulating film 115, an ON state, that is, a conductive state is realized. This phenomenon can be accelerated by raising the temperature. That is, there is a phenomenon in which the gate insulating film 115 is destroyed or melted even when the applied voltage is 0 V at a melting point of the gate insulating film 115.

When energy of the difference between the temperature and melting point of the gate insulating film 115 is given to the gate insulating film 115 at below the melting point, the bond of atoms is dissociated by vibration energy of atoms in the gate insulating film 115, and the molten state of the gate insulating film 115 is realized. For this reason, the temperature of the gate insulating film 115 rises by the IR laser by giving a part of the energy required for destruction of the gate insulating film 115 (realization of a programmed state) and destruction of the conductive path 131 (realization of an erase state) as thermal energy. Furthermore, the program state and the erase state can be realized by adding the energy of the difference from the drive circuit 17 as power energy. In other words, the sum of the power energy supplied from the drive circuit 17 and the thermal energy from the IR laser emitted to the gate 113 is energy required for melting the gate insulating film 115.

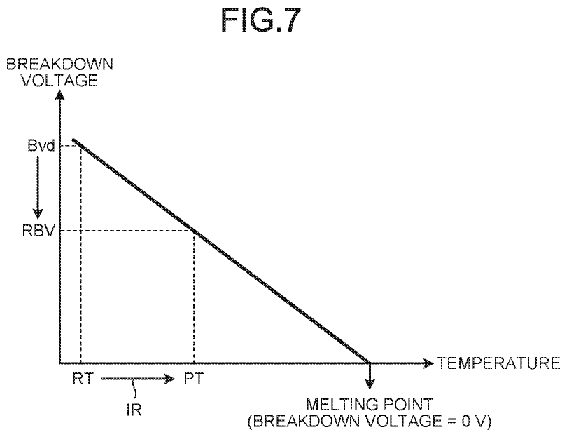

FIG. 7 is a graph indicating an example of the relationship between the breakdown voltage and the temperature. As illustrated in FIG. 7, the breakdown voltage at room temperature RT (hereinafter referred to as “room temperature breakdown voltage”) is Bvd, but the breakdown voltage at the temperature at the first write or the second write (hereinafter referred to as “program temperature”) PT is a voltage RBV lower than the room temperature breakdown voltage Bvd. A decrease in the breakdown voltage corresponds to a decrease in breakdown energy and is realized by irradiating the gate 113 with an IR laser. As illustrated in FIG. 7, by locally irradiating the gate 113 with the IR laser and raising the temperature of the gate insulating film 115 and the conductive path 131, polysilicon is easily melted, and the first voltage and the second voltage can be reduced.

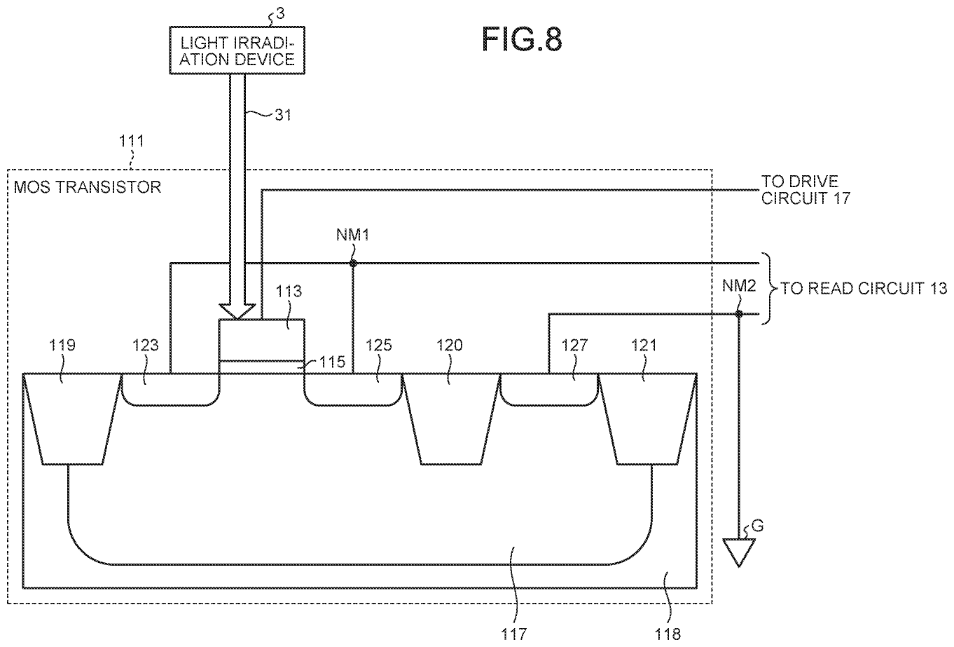

FIG. 8 is a view illustrating an example of the positional relationship between the MOS transistor 111 and the light irradiation device 3. The light irradiation device 3 generates an IR laser 31. The light irradiation device 3 is installed outside the semiconductor memory device 1. In the first write and the second write, the light irradiation device 3 is disposed at a position where the IR laser 31 reaches the gate 113 (hereinafter referred to as “irradiation position”), for example, immediately above the gate 113. The light irradiation device 3 is mounted on, for example, a tester that inspects operation of the semiconductor memory device 1. Positioning between the light irradiation device 3 and the gate 113 is appropriately executed by a tester. Note that the positioning between the light irradiation device 3 and the gate 113 does not have to be exact since the first write and the second write are realized by overlapping the irradiation position of the IR laser 31 and the gate 113 to which a voltage is applied. Further, the irradiation time of the IR laser 31 by the light irradiation device 3 may be appropriately controlled by the control circuit 15 according to the material of the gate 113 such that the temperature of the gate insulating film 115 after the IR laser 31 irradiation does not exceed the melting point.

Note that, when the gate 113 is composed of a metal gate having a metal as a material, the wavelength of the light generated by the light irradiation device 3 is selected as a wavelength that is different from the above-described infrared rays and is absorbed by the metal gate. The laser with which the metal gate is irradiated is, for example, a green laser. In addition, the irradiation time of the laser with which the metal gate is irradiated is appropriately adjusted according to the metal constituting the metal gate, unlike the irradiation time of the IR laser 31.

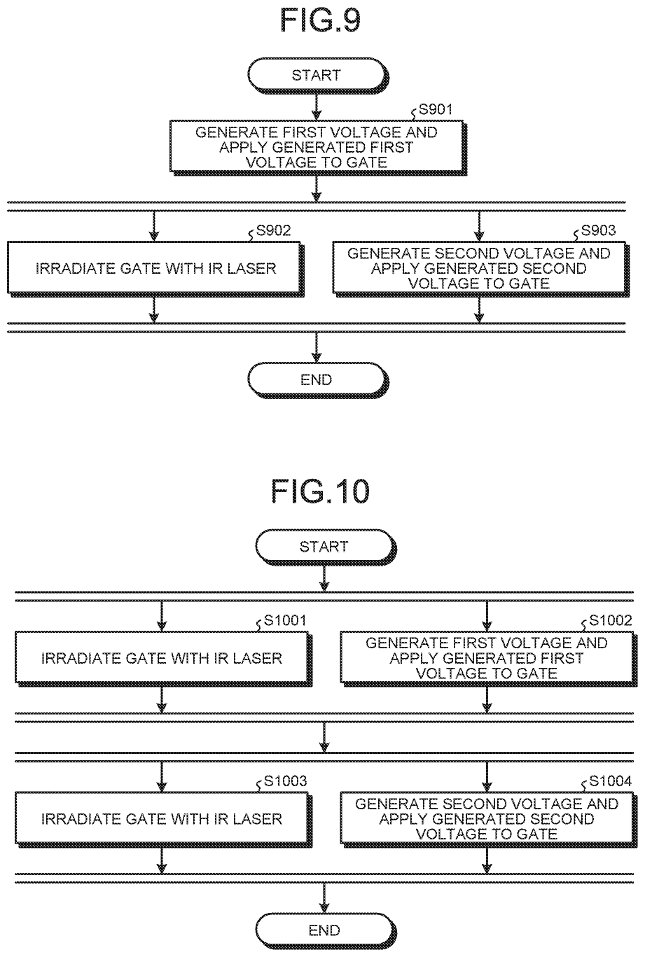

FIG. 9 is a flowchart illustrating an example of a procedure of assist erase processing. The optical assist erase processing is a process including a process of irradiating the gate 113 with the IR laser 31 in the second write.

(Optical Assist Erase Processing)

(Step S901)

The first voltage generation circuit 171 generates a first voltage. The control circuit 15 controls the switch circuit 175 in order to apply the first voltage to the gate 113. With this control, the switch circuit 175 turns on the fifth PMOS transistor PT5 and turns off the sixth PMOS transistor PT6. As a result, the first voltage is applied to the gate 113 over the first application time, and the gate insulating film 115 is destroyed. At this time, as illustrated in FIG. 4, the conductive path 131 is formed between the first AA 123 and the gate 113.

(Step S902)

As illustrated in FIG. 8, the light irradiation device 3 is disposed at the irradiation position. The light irradiation device 3 generates an IR laser 31. The irradiation time of the IR laser 31 is set in advance according to the voltage value of the second voltage and the second application time. The light irradiation device 3 irradiates the gate 113 with the generated IR laser 31 over the irradiation time. Thereby, the assistance which provides the heat for fusing the conductive path 131 is realized.

(Step S903)

The second voltage generation circuit 173 generates the second voltage. The control circuit 15 controls the switch circuit 175 in order to apply the first voltage to the gate 113. With this control, the switch circuit 175 turns off the fifth PMOS transistor PT5 and turns on the sixth PMOS transistor PT6. As a result, the second voltage is applied to the gate 113 over the second application time, and the conductive path 131 is fused. At this time, as illustrated in FIG. 5, the conductive path 131 is fused, and the fused region 133 is formed.

Thus, the first write and the second write in this application example are completed. As illustrated in FIG. 9, the process in Step S902 and the process in Step 903 are executed as parallel processes. Note that, as an alternative to the parallel processes, the process in Step S903 may be sequentially performed after the process in Step S902. At this time, the generation of the second voltage may be performed before Step S902.

FIG. 10 is a flowchart illustrating an example of the procedure of optical assist writing processing. The optical assist writing processing is a process of irradiating the gate 113 with the IR laser 31 in the first write and the second write. Note that the process in Step S1003 in FIG. 10 is substantially the same as the process in Step S902, and therefore, different process contents will be described. Further, since the process in Step S1004 is the same as the process in Step S903, the description thereof will be omitted.

(Optical Assist Writing Processing)

(Step S1001)

As illustrated in FIG. 8, the light irradiation device 3 is disposed at the irradiation position. The light irradiation device 3 generates an IR laser 31. The irradiation time of the IR laser 31 in this step (hereinafter referred to as “first irradiation time”) is set in advance according to the voltage value of the first voltage and the first application time. The light irradiation device 3 irradiates the gate 113 with the generated IR laser 31 over the first irradiation time. Thereby, assistance of overheating of the polysilicon is realized.

(Step S1002)

The first voltage generation circuit 171 generates a first voltage. The control circuit 15 controls the switch circuit 175 in order to apply the first voltage to the gate 113. With this control, the switch circuit 175 turns on the fifth PMOS transistor PT5 and turns off the sixth PMOS transistor PT6. As a result, the first voltage is applied to the gate 113 over the first application time, and the conductive path 131 is formed as illustrated in FIG. 4.

Thus, the first write in this application example is completed. As illustrated in FIG. 10, the process in Step S1001 and the process in Step 1002 are executed as parallel processes. Note that, as an alternative to the parallel processing, the process in Step S1002 may be executed sequentially after the process in Step S1001. At this time, the generation of the first voltage may be performed before Step S1001.

(Step S1003)

The irradiation time of the IR laser 31 in this step (hereinafter referred to as “second irradiation time”) is set in advance according to the voltage value of the second voltage and the second application time. The light irradiation device 3 irradiates the gate 113 with the generated IR laser 31 over the second irradiation time. For example, the second irradiation time is set longer than the first irradiation time. Further, the intensity of the IR laser 31 in the second write may be larger than the intensity of the IR laser 31 in the first write.

Note that the manufacturing method of the semiconductor memory device 1 described above is not limited to the above-described processing procedure. For example, as a modification of the application example, the gate 113 may be irradiated with the IR laser 31 in parallel with the application of the first voltage, and the gate 113 may not be irradiated with the IR laser 31 when the second write is performed.

According to an application example of the embodiment, a first voltage that destroys the gate insulating film 115 in the MOS transistor 111 is applied to the gate 113, after the application of the first voltage, the second voltage lower than the first voltage is applied to the gate 113, and in at least one of the application of the first voltage and the application of the second voltage, the gate 113 is irradiated with light having a wavelength corresponding to the material of the gate 113. As a result, according to the manufacturing method of the semiconductor memory device 1 in the application example, the initial write (first write) time, that is, the manufacturing time of the semiconductor memory device 1, can be shortened, and the effect of reducing the manufacturing cost of the semiconductor memory device 1 can be obtained.

Further, according to the application example of the embodiment, the temperature of the gate 113 is increased by the irradiation with the IR laser 31, such that the voltage related to writing can be reduced, and an erasing current for erasing the first write can be reduced. As a result, in the application example of the embodiment, manufacturing yield can be improved, and the manufacturing cost of the semiconductor memory device 1 can be further reduced. In addition, according to the application example of the embodiment, since the power related to one-bit writing can be reduced, the power required for the drive circuit 17 can be reduced, and multi-bit simultaneous writing (hereinafter referred to as “multi-bit simultaneous writing”) can be easily realized. For example, by adjusting the intensity of the IR laser 31 and the second irradiation time according to the number of bits related to multi-bit simultaneous writing, arbitrary multi-bit simultaneous writing can be realized without changing the power required for the drive circuit 17. Further, by adjusting the intensity of the IR laser 31 and the second irradiation time, the power required for the drive circuit 17 can be reduced, and therefore the area of the drive circuit 17 can be reduced, that is, the area of the internal circuit in the semiconductor memory device 1 can be reduced.

From the above, according to the manufacturing method of the semiconductor memory device 1 according to the application example, the semiconductor memory device 1 that can be written twice can be provided without using two elements with different breakdown characteristics. The semiconductor memory device 1 according to the embodiment can be used as a device that stores data such as IDs and passwords different for each user and discards the data.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device, comprising:
a MOS transistor having a gate and a gate insulating film; and
a drive circuit coupled to the gate and configured to supply a first voltage that destroys the gate insulating film or a second voltage lower than the first voltage;
wherein the drive circuit
applies the first voltage to the gate in a first write to the MOS transistor, and
applies the second voltage to the gate in a second write to the MOS transistor.

2. The semiconductor memory device according to claim 1, wherein the drive circuit comprises
a first voltage generation circuit configured to generate the first voltage,
a second voltage generation circuit configured to generate the second voltage, and
a switch circuit configured to switch between a first coupling state in which the first voltage generation circuit and the gate are coupled and a second coupling state in which the second voltage generation circuit and the gate are coupled.

3. The semiconductor memory device according to claim 2, wherein
the switch circuit
switches to the first coupling state in the first write, and
switches to the second coupling state in the second write.

4. The semiconductor memory device according to claim 3, wherein
in the first write, the gate insulating film is destroyed, and a conductive path that makes the gate insulating film conductive is formed, and
in the second write, the conductive path is fused.

5. The semiconductor memory device according to claim 4, wherein
in the first write, the first voltage is a voltage corresponding to a current that does not fuse the conductive path, and an application time during which the first voltage is applied to the gate is set so as to form the conductive path.

6. The semiconductor memory device according to claim 4, wherein
in the second write, an application time during which the second voltage is applied to the gate is set so as to form a fused region by fusing the conductive path.

7. The semiconductor memory device according to claim 4, wherein
in at least one of the first write and the second write, the gate is irradiated with light having a wavelength corresponding to a material of the gate.

8. The semiconductor memory device according to claim 7, further comprising:
a control circuit configured to control the irradiation time of the light such that a temperature of the gate insulating film does not exceed a melting point.

9. The semiconductor memory device according to claim 7, wherein
when the gate material is polysilicon, the light is an infrared laser.

10. The semiconductor memory device according to claim 7, wherein
when the gate is a metal gate made of a metal, the light has a wavelength absorbed by the metal gate.

11. A method of manufacturing a semiconductor memory device, wherein
in a MOS transistor having a gate and a gate insulating film, a first voltage that destroys the gate insulating film is applied to the gate,
after applying the first voltage, a second voltage lower than the first voltage is applied to the gate, and
in at least one of the application of the first voltage and the application of the second voltage, the gate is irradiated with light having a wavelength corresponding to a material of the gate.

12. The method of manufacturing a semiconductor memory device according to claim 11, comprising:
forming a conductive path that destroys the gate insulating film by applying the first voltage and brings the gate insulating film into a conductive state; and
fusing the conductive path by applying the second voltage.

13. The method of manufacturing a semiconductor memory device according to claim 12, wherein
the first voltage is a voltage corresponding to a current that does not fuse the conductive path, and an application time during which the first voltage is applied to the gate is set so as to form the conductive path.

14. The method of manufacturing a semiconductor memory device according to claim 12, wherein
an application time during which the second voltage is applied to the gate is set so as to form a fused region by fusing the conductive path.

15. The method of manufacturing a semiconductor memory device according to claim 11, wherein
an irradiation time of the light is controlled such that a temperature of the gate insulating film does not exceed a melting point.

16. The method of manufacturing a semiconductor memory device according to claim 11, wherein
when the gate material is polysilicon, the light is an infrared laser.

17. The method of manufacturing a semiconductor memory device according to claim 11, wherein
when the gate is a metal gate made of a metal, the light has a wavelength absorbed by the metal gate.

18. A semiconductor memory device, comprising:
a plurality of MOS transistors having a gate and a gate insulating film; and
a drive circuit coupled to the gate and configured to supply a first voltage that destroys the gate insulating film or a second voltage lower than the first voltage;
wherein the drive circuit applies the first voltage to the gate in a first write to the MOS transistor, and applies the second voltage to the gate in a second write to the MOS transistor,
a MOS transistor which has been applied with the first voltage among a plurality of the MOS transistors has a region relating to a conductive path formed by destruction of the gate insulating film, and
a MOS transistor which has been applied with the second voltage after the application of the first voltage among a plurality of the MOS transistors has a fused region formed by fusing a conductive path formed by destruction of the gate insulating film.
